(19) United States
(12) Patent Application Publication
(10) Pub. No.: US 2017/0115540 A1
(43) Pub. Date: Apr. 27, 2017

(54) Thin Film Transistor and its Manufacturing Method, Array Substrate, Manufacturing Method and Display Device

(71) Applicants: BOE Technology Group Co., Ltd.; HEFEI BOE Optoelectronics Technology Co., Ltd., Hefei (CN)

(72) Inventors: Ping Song, Beijing (CN); Hongmin Li, Beijing (CN); Wei Xue, Beijing (CN); Zhifu Dong, Beijing (CN); Honggang Gu, Beijing (CN); Xiaohe Li, Beijing (CN)

(73) Assignees: BOE Technology Group Co., Ltd., Beijing (CN); HEFEI BOE Optoelectronics Technology Co., Ltd., Hefei (CN)

(21) Appl. No.: 15/034,827

(22) PCT Filed: Sep. 18, 2015
(86) PCT No.: PCT/CN2015/089995

§ 371 Date: May 5, 2016

(30) Foreign Application Priority Data
May 6, 2015 (CN) 201510227721.0

(51) Int. Cl. G02F 1/1362; H01L 27/12; G02F 1/1368

(52) U.S. Cl. CPC G02F 1/136209; G02F 1/1368; H01L 27/124; H01L 27/127; G02F 1/133723

(57) ABSTRACT

A thin film transistor and its manufacturing method are provided. The thin film transistor comprises an active layer on a substrate, and further comprises an ultraviolet light blocking layer positioned on a side of the active layer away from the substrate, and the active layer has a projection on the substrate which is within a projection of the ultraviolet light blocking layer on the substrate. The active layer is completely covered by the ultraviolet light blocking layer, and during the photo-alignment process, the ultraviolet light blocking layer can effectively eliminate the influence of the ultraviolet light on the active layer of the thin film transistor and ensure that the performance of the thin film transistor will not be affected by irradiation of the ultraviolet light.

### TECHNICAL FIELD

Embodiments of the present disclosure relate to a thin film transistor and its manufacturing method, an array substrate and its manufacturing method, a display panel and a display device.

### BACKGROUND

Before cell-assembling process of thin film transistor liquid crystal display (TFT-LCD), printing an alignment film (PI) and alignment process are performed on the thin film transistor (TFT) substrate and the color filter (CF) substrate respectively. A commonly-used alignment process for PI is a monotype rubbing process in which alignment is achieved by rubbing process and an alignment of liquid crystal molecules is controlled by the alignment film thereby ensuring the liquid crystal molecules to be arranged in a proper direction. As requirements for resolution, aperture ratio and contrast are increasingly raised, the rubbing process is gradually replaced by photo-alignment technology. The photo-alignment technology utilizes the ultraviolet light to perform photo-alignment on the alignment material with high sensitivity to light and good stability and thus has advantages such as high aperture ratio, high contrast and quick response, while effectively preventing electro static discharge (ESD) from being frequently generated in the rubbing process, and reducing various defects such as stripes and particles occurring in PI.

However, when the ultraviolet light is utilized to irradiate in the photo-alignment process, the property of the active layer of the TFT device in the pixel structure will be affected and thus leakage current is increased, thereby affecting the property of the TFT and causing defects such as crosstalk and etc.

### SUMMARY

At least one embodiment of the present disclosure provides a thin film transistor comprising an active layer on a substrate, and further comprising an ultraviolet light blocking layer disposed on a side of the active layer away from the substrate, and the active layer having a projection on the substrate which is within a projection of the ultraviolet light blocking layer on the substrate.

In the above thin film transistor, the active layer is completely covered by the ultraviolet light blocking layer in a direction perpendicular to the substrate. The ultraviolet light blocking layer is configured to block the ultraviolet light. In the photo-alignment process, the ultraviolet light blocking layer can effectively eliminate influence of the ultraviolet light on the active layer of the thin film transistor and thus ensure that the performance of the thin film transistor will not be affected by irradiation of the ultraviolet light.

Therefore, the performance of the above thin film transistor will not be affected by the irradiation of the ultraviolet light during the photo-alignment process.

In one embodiment of the present disclosure, the thin film transistor further comprises source and drain electrodes disposed on a side of the active layer away from the substrate, and the ultraviolet light blocking layer is disposed on a side of the source and drain electrodes away from the substrate.

At least one embodiment of the present disclosure provides an array substrate comprising a substrate and further comprising any one of the above-described thin film transistors.

In one embodiment of the present disclosure, the material of the ultraviolet light blocking layer is ultraviolet light absorbing material.

In one embodiment of the present disclosure, the ultraviolet light absorbing material is ITO.

In one embodiment of the present disclosure, the array substrate further comprises a pixel electrode disposed on a side of the source and drain electrodes of the thin film transistor away from the substrate, where the ultraviolet light blocking layer is disposed on a side of the source and drain electrodes away from the substrate, the ultraviolet light blocking layer is arranged in the same layer as the pixel electrode; or the array substrate further comprises a common electrode disposed on a side of the source and drain electrodes of the thin film transistor away from the substrate, where the ultraviolet light blocking layer is disposed on a side of the source and drain electrodes away from the substrate, the ultraviolet light blocking layer is arranged in the same layer as the common electrode.

A display panel comprises any one of the above-described array substrates.

A display device comprises any one of the above-described display panel.

A manufacturing method of a thin film transistor comprises:

forming an active layer on a substrate;

forming an ultraviolet light blocking layer on a side of the active layer away from the substrate, wherein the active layer has a projection on the substrate which is within a projection of the ultraviolet light blocking layer on the substrate.

In one embodiment of the present disclosure, after the active layer is formed on the substrate and before the ultraviolet light blocking layer is formed on the side of the active layer away from the substrate, the manufacturing method further comprises:

forming source and drain electrodes on a side of the active layer away from the substrate.

A manufacturing method of an array substrate comprises the manufacturing method of the thin film transistor according to any one of the above-described technical solutions.

In one embodiment of the present disclosure, material of the ultraviolet light blocking layer is ultraviolet light absorbing material.

In one embodiment of the present disclosure, the material of the ultraviolet light blocking layer is ITO.

In one embodiment of the present disclosure, when the array substrate further comprises a pixel electrode positioned on a side of the source and drain electrodes of the thin film transistor away from the substrate and the ultraviolet light blocking layer is arranged in the same layer as the pixel electrode, the step of forming the ultraviolet light blocking layer on the side of the active layer away from the substrate specifically comprises:

forming a pixel electrode layer on the side of the source and drain electrodes of the thin film transistor away from the substrate, and forming patterns of the pixel electrode and patterns of the ultraviolet light blocking layer by a single-patterning process.

In one embodiment of the present disclosure, when the array substrate further comprises a common electrode positioned on a side of the source and drain electrodes of the thin film transistor away from the substrate and the ultraviolet light blocking layer is arranged in the same layer as the common electrode, the step of forming the ultraviolet light blocking layer on the side of the active layer away from the substrate comprises:

forming a common electrode layer on the side of the source and drain electrodes of the thin film transistor away from the substrate, and forming patterns of the common electrode and patterns of the ultraviolet light blocking layer by a single-patterning process.

### BRIEF DESCRIPTION OF THE DRAWINGS

In order to clearly illustrate the technical solutions of the embodiments of the disclosure, the drawings of the embodiments will be briefly described in the following; it is obvious that the drawings described below are only related to some embodiments of the disclosure and thus are not limitative of the disclosure.

FIG. 1 is an illustrative view of partial structural of an array substrate according to one embodiment of the present disclosure;

FIG. 2 is an illustrative view of partial sectional structural of an array substrate according to one embodiment of the present disclosure; and

FIG. 3 is an illustrative flow chart of a manufacturing method of a thin film transistor according to one embodiment of the present disclosure.

### DETAILED DESCRIPTION

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

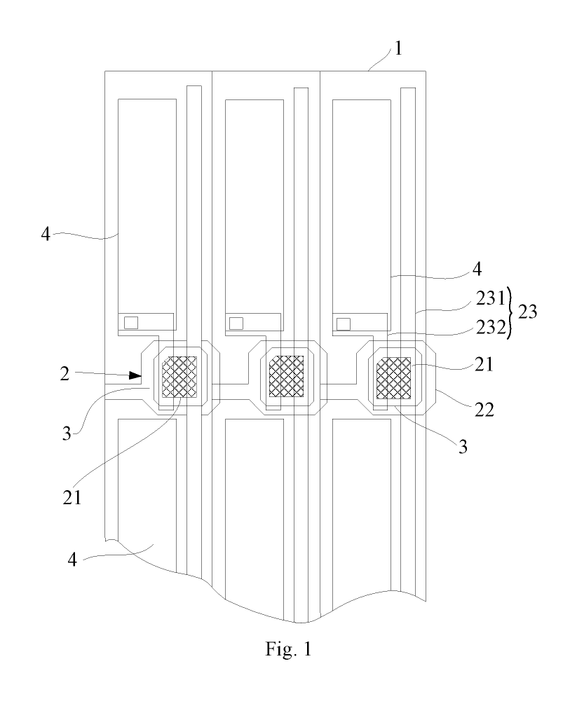

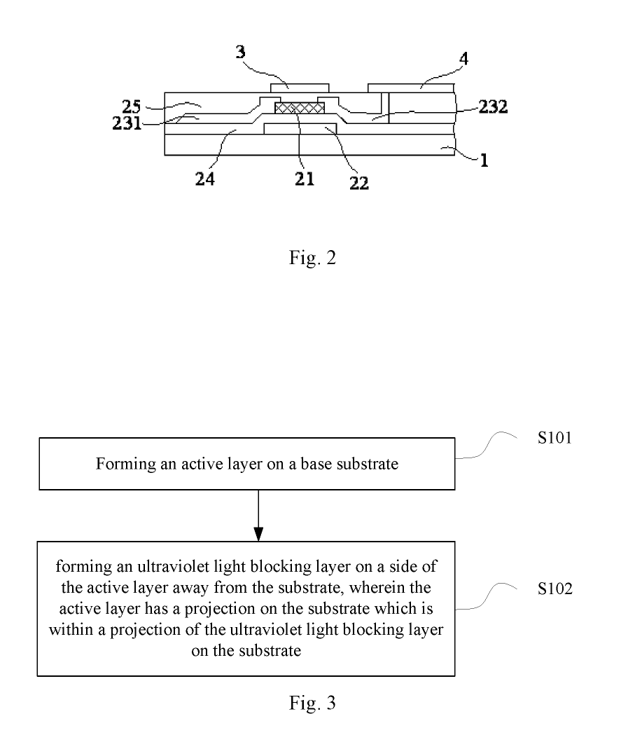

As illustrated in FIG. 1 and FIG. 2, one embodiment according to the present disclosure provides a thin film transistor 2 comprising an active layer 21 positioned on the substrate 1 and further comprising an ultraviolet light blocking layer 3 disposed on a side of the active layer 21 away from the substrate. The active layer 21 has a projection on the substrate 1 which is within a projection of the ultraviolet light blocking layer 3 on the substrate 1.

In the above-described thin film transistor 2, the active layer 21 is completely covered by the ultraviolet light blocking layer 3. The ultraviolet light blocking layer 3 can block ultraviolet light, so that the ultraviolet light blocking layer 3 can effectively protect the active layer 21 from being affected by ultraviolet light during the photo-alignment process, and thus it can be ensured that the performance of the thin film transistor 2 will not be influenced by the irradiation of ultraviolet light. Therefore, the performance of the above thin film transistor 2 will not be affected by the irradiation of ultraviolet light during the photo-alignment process.

As illustrated in FIG. 1 and FIG. 2, in one embodiment according to the present disclosure, the thin film transistor 2 can further comprise source and drain electrodes 23 positioned on a side of the active layer 21 away from the substrate 1. The ultraviolet light blocking layer 3 is positioned on a side of the source and drain electrodes 23 away from the substrate 1. As illustrated in FIG. 2, the thin film transistor 2 can further comprise a gate electrode 22 and a gate insulation layer 24 which are disposed between the active layer 21 and the substrate 1.

In one embodiment according to the present disclosure, the ultraviolet light blocking layer 3 can be made of ultraviolet light absorbing material. The ultraviolet light absorbing material has a function of blocking ultraviolet light by absorbing ultraviolet light.

In one embodiment according to the present disclosure, the above ultraviolet light absorbing material can be ITO (indium tin oxide).

Of course, material for the ultraviolet light blocking layer 3 is not limited to the above-described ultraviolet light absorbing material, but can be ultraviolet light reflecting material such as metallic material.

As illustrated in FIG. 1 and FIG. 2, one embodiment according to the present disclosure further provides an array substrate comprising a thin film transistor 2 as described in any one of the above embodiments.

As illustrated in FIG. 1 and FIG. 2, in one embodiment according to the present disclosure, the above array substrate can further comprise a pixel electrode 4 positioned on a side of source and drain electrodes 23 of the thin film transistor 2 which faces away from the substrate 1. A passivation layer 25 is formed between the source and drain electrodes 23 and the pixel electrode 4. Since the pixel electrode 4 in the array substrate can be made of materials such as ITO, the ultraviolet light blocking layer 3 can be arranged in the same layer as the pixel electrode 4 when the ultraviolet light blocking layer 3 is positioned on a side of the source and drain electrodes 23 away from the substrate 1.

In one embodiment according to the present disclosure, the array substrate can comprise a common electrode positioned on a side of the pixel electrode 4 away from the substrate 1, in addition to the pixel electrode 4 positioned on a side of the source and drain electrodes 23 of the thin film transistor 2 which faces away from the substrate 1. An insulation layer is formed between the pixel electrode 4 and the common electrode. Since the common electrode in the array substrate can be also made of ITO, the ultraviolet light blocking layer 3 can be arranged in the same layer as the common electrode when the ultraviolet light blocking layer 3 is positioned on a side of the source and drain electrodes 23 which faces away from the substrate 1.

The fact that the ultraviolet light blocking layer 3 is arranged in the same layer as the pixel electrode 4 or the common electrode in the array substrate when the ultraviolet light blocking layer is made of ITO, can simplify the manufacturing process and can prevent the electrical conduction performances of the electrical conduction structures such as the active layer 21, the gate electrode 22, and the source and drain electrodes 23 of the thin film transistor 2 from being affected by the ultraviolet light, and thus avoiding any influence on the performance of the thin film transistor 2.

Of course, the ultraviolet light blocking layer 3 can also be formed between the active layer 21 and the source and drain electrodes 23 of the thin film transistor 2. When the ultraviolet light blocking layer 3 is formed between the active layer 21 and the source and drain electrodes 23 of the thin film transistor 2, the material of the ultraviolet light blocking layer 3 can be non-conductive material so as to avoid any influence on the performance of the thin film transistor 2.

At least one embodiment according to the present disclosure further provides a display panel comprising an array substrate as described in any one of the above embodiments. The array substrate in the display panel will not malfunction due to irradiation of ultraviolet light and will have stable and reliable performance.

At least one embodiment according to the present disclosure further provides a display device comprising the display panel as described in the above embodiment. The array substrate in the display device has stable and reliable performance and malfunctions such as crosstalk will be eliminated.

As illustrated in FIG. 1, FIG. 2 and FIG. 3, a method for manufacturing any one of the above-described thin film transistors comprises:

Step S101, forming the active layer 21 on the substrate 1;

Step S102, forming the ultraviolet light blocking layer 3 on a side of the active layer 21 away from the substrate 1, wherein the active layer 21 has a projection on the substrate 1 which is within a projection of the ultraviolet light blocking layer 3 on the substrate 1.

In the thin film transistor 2 made by the above manufacturing method, the active layer 21 is completely covered by the ultraviolet light blocking layer 3 and the ultraviolet light blocking layer 3 can block ultraviolet light. Therefore, during the photo-alignment process, the ultraviolet light blocking layer 3 can effectively eliminate the influence of the ultraviolet light on the active layer 21 and thus ensure that the performance of the thin film transistor 2 will not be affected by the irradiation of the ultraviolet light.

As illustrated in FIG. 1 and FIG. 2, on the basis of the above embodiments, in one modified embodiment according to the present disclosure, after the active layer 21 is formed on the substrate 1 and before the ultraviolet light blocking layer 3 is formed on a side of the active layer 21 away from the substrate 1, the method further can comprise a step of forming source and drain electrodes on a side of the active layer 21 away from the substrate 1.

On the basis of the above embodiments, in one modified embodiment according to the present disclosure, material for the ultraviolet light blocking layer 3 can be ultraviolet light absorbing material. The ultraviolet light absorbing material has a function of blocking ultraviolet light by absorbing ultraviolet light.

In one embodiment according to the present disclosure, the above ultraviolet light absorbing material can be ITO.

Of course, material for the ultraviolet light blocking layer 3 is not limited to the ultraviolet light absorbing material as described in the above embodiment, but can be ultraviolet light reflecting material such as metals as well.

A method for manufacturing any one of the above-described array substrates comprises the manufacturing method process of the thin film transistor as described in any one of the above embodiments.

In one embodiment according to the present disclosure, as illustrated in FIG. 1 and FIG. 2, when the array substrate further comprises a pixel electrode 4 positioned on a side of the source and drain electrodes 23 of the thin film transistor 2 which faces away from the substrate 1 and the ultraviolet light blocking layer 3 is disposed in the same layer as the pixel electrode 4, the Step S102 of forming the ultraviolet light blocking layer 3 on the side of the active layer 21 away from the substrate 1 can comprise:

forming a passivation layer 25 on a side of the source and drain electrodes 23 of the thin film transistor 2 which faces away from the substrate 1, forming a pixel electrode layer on the passivation layer 25, and forming a pattern of the pixel electrode 4 and a pattern of the ultraviolet light blocking layer 3 by a single-patterning process.

In one embodiment according to the present disclosure, when the array substrate further comprises a common electrode positioned on a side of the source and drain electrodes 23 of the thin film transistor 2 which faces away from the substrate 1 and the ultraviolet light blocking layer 3 is arranged in the same layer as the common electrode, the Step S102 of forming the ultraviolet light blocking layer 3 on the side of the active layer 21 away from the substrate 1 can comprise:

forming a pixel electrode 4 on a side of the source and drain electrodes 23 of the thin film transistor 2 away from the substrate 1, forming an insulation layer on a side of the pixel electrode 4 away from the substrate 1, forming a common electrode layer on the insulation layer, and forming a pattern of the common electrode and a pattern of the ultraviolet light blocking layer 3 by a single-patterning process.

The foregoing are merely exemplary embodiments of the disclosure, but are not used to limit the protection scope of the disclosure. The protection scope of the disclosure shall be defined by the attached claims.

The present disclosure claims priority of Chinese Patent Application No. 201510227721.0 filed on May 6, 2015, the disclosure of which is hereby entirely incorporated by reference as a part of the present disclosure.

1. A thin film transistor comprising an active layer on a substrate, wherein the thin film transistor further comprises an ultraviolet light blocking layer positioned on a side of the active layer away from the substrate, and the active layer has a projection on the substrate which is within a projection of the ultraviolet light blocking layer on the substrate.

2. The thin film transistor according to claim 1, further comprising source and drain electrodes positioned on a side of the active layer away from the substrate, wherein the ultraviolet light blocking layer is positioned on a side of the source and drain electrodes away from the substrate.

3. An array substrate comprising a substrate, it further comprises the thin film transistor according to claim 1.

4. The array substrate according to claim 3, wherein material for the ultraviolet light blocking layer is ultraviolet light absorbing material.

5. The array substrate according to claim 4, wherein the ultraviolet light absorbing material is ITO.

6. The array substrate according to claim 3, wherein
the array substrate further comprises a pixel electrode positioned on a side of the source and drain electrodes of the thin film transistor which faces away from the substrate, and when the ultraviolet light blocking layer is positioned on a side of the source and drain electrodes away from the substrate, the ultraviolet light blocking layer is arranged in the same layer as the pixel electrode; or
the array substrate further comprises a common electrode positioned on a side of the source and drain electrodes of the thin film transistor away from the substrate, and when the ultraviolet light blocking layer is positioned on a side of the source and drain electrodes away from the substrate, the ultraviolet light blocking layer is arranged in the same layer as the common electrode.

7. A display panel comprising the array substrate according to claim 3.

8. A display device comprising the display panel according to claim 7.

9. A manufacturing method of a thin film transistor, comprising:
forming an active layer on a substrate;
forming an ultraviolet light blocking layer on a side of the active layer away from the substrate, wherein the active layer has a projection on the substrate which is within a projection of the ultraviolet light blocking layer on the substrate.

10. The manufacturing method according to claim 9, wherein after forming the active layer on the substrate and before forming the ultraviolet light blocking layer on the side of the active layer away from the substrate, the manufacturing method further comprises:
forming source and drain electrodes on a side of the active layer away from the substrate.

11. A manufacturing method of an array substrate comprising the manufacturing method of the thin film transistor according to claim 9.

12. The manufacturing method according to claim 11, wherein material for the ultraviolet light blocking layer is ultraviolet light absorbing material.

13. The manufacturing method according to claim 12, wherein material for the ultraviolet light blocking layer is ITO.

14. The manufacturing method according to claim 13, wherein
when the array substrate further comprises a pixel electrode positioned on a side of the source and drain electrodes of the thin film transistor which faces away from the substrate and the ultraviolet light blocking layer is arranged in the same layer as the pixel electrode, the step of forming the ultraviolet light blocking layer on the side of the active layer away from the substrate comprises:
forming a pixel electrode layer on a side of the source and drain electrodes of the thin film transistor which faces away from the substrate, and forming a pattern of the pixel electrode and a pattern of the ultraviolet light blocking layer by a single-patterning process.

15. The manufacturing method according to claim 13, wherein
when the array substrate further comprises a common electrode positioned on a side of the source and drain electrodes of the thin film transistor which faces away from the substrate and the ultraviolet light blocking layer is arranged in the same layer as the common electrode, the step of forming the ultraviolet light blocking layer on the side of the active layer away from the substrate comprises:
forming a common electrode layer on a side of the source and drain electrodes of the thin film transistor which faces away from the substrate, and forming a pattern of the common electrode and a pattern of the ultraviolet light blocking layer by a single-patterning process.

16. An array substrate comprising a substrate, it further comprises the thin film transistor according to claim 2.

17. The array substrate according to claim 16, wherein material for the ultraviolet light blocking layer is ultraviolet light absorbing material.

18. The array substrate according to claim 4, wherein
the array substrate further comprises a pixel electrode positioned on a side of the source and drain electrodes of the thin film transistor which faces away from the substrate, and when the ultraviolet light blocking layer is positioned on a side of the source and drain electrodes away from the substrate, the ultraviolet light blocking layer is arranged in the same layer as the pixel electrode; or
the array substrate further comprises a common electrode positioned on a side of the source and drain electrodes of the thin film transistor away from the substrate, and when the ultraviolet light blocking layer is positioned on a side of the source and drain electrodes away from the substrate, the ultraviolet light blocking layer is arranged in the same layer as the common electrode.

19. The array substrate according to claim 5, wherein
the array substrate further comprises a pixel electrode positioned on a side of the source and drain electrodes of the thin film transistor which faces away from the substrate, and when the ultraviolet light blocking layer is positioned on a side of the source and drain electrodes away from the substrate, the ultraviolet light blocking layer is arranged in the same layer as the pixel electrode; or
the array substrate further comprises a common electrode positioned on a side of the source and drain electrodes of the thin film transistor away from the substrate, and when the ultraviolet light blocking layer is positioned on a side of the source and drain electrodes away from the substrate, the ultraviolet light blocking layer is arranged in the same layer as the common electrode.

20. A manufacturing method of an array substrate comprising the manufacturing method of the thin film transistor according to claim 10.
